(19) United States
(12) Patent Application Publication
(10) Pub. No.: US 2021/0124705 A1
(43) Pub. Date: Apr. 29, 2021

(54) NAND INTERFACE DEVICE TO BOOST OPERATION SPEED OF A SOLID-STATE DRIVE

(71) Applicant: Integrated Device Technology, Inc., San Jose, CA (US)

(72) Inventors: Shubing Zhai, San Jose, CA (US); Changxi Xu, San Jose, CA (US)

(21) Appl. No.: 16/667,194

(22) Filed: Oct. 29, 2019

(51) Int. Cl. G06F 13/40; G11C 16/04

(52) U.S. Cl. CPC G06F 13/4027; G11C 16/0483; G06F 13/4022

(57) ABSTRACT

An apparatus including a front port, a plurality of back ports and a plurality of switches. The front port may be configured to send/receive data to/from a controller. The plurality of back ports may each be configured to send/receive the data to/from one of a plurality of logical units of a memory. The plurality of switches may each be configured to connect the front port to one of the back ports in response to an input. The input may be received from the controller and may also be presented to the memory.

### FIELD OF THE INVENTION

The invention relates to solid-state drives generally and, more particularly, to a method and/or apparatus for implementing a NAND interface device to boost operation speed of a solid-state drive.

### BACKGROUND

Solid-state drives (SSDs) are a computer storage medium that have increased performance and reduced power consumption compared to hard disk drives. A solid-state drive (SSD) usually consists of a flash controller that communicates with a few NAND channels. Each NAND channel connects to one or more NAND targets. Each target may include one or more logical units (LUNs).

In a NAND channel where the flash controller connects to a group of NAND targets, there are inherent performance limits. All of the targets and LUNs share the same NAND bus. The flash controller may see all of the LUNs as a lumped load. Since the LUNs are seen as a lumped load, the NAND bus cannot operate at the maximum rated speed that a LUN is capable of operating at. Furthermore, at any moment, only one of the LUNs could move data to or from the flash controller. The flash controller has to slow down the transfer speed of the NAND bus due to the added loading of multiple LUNs, and the signal interference issue of addressing multiple LUNs. Signal interference may be particularly problematic when there are reflections as a result of the LUNs residing in a different package or port.

It would be desirable to implement a NAND interface device to boost operation speed of a solid-state drive.

### SUMMARY

The invention concerns an apparatus including a front port, a plurality of back ports and a plurality of switches. The front port may be configured to send/receive data to/from a controller. The plurality of back ports may each be configured to send/receive the data to/from one of a plurality of logical units of a memory. The plurality of switches may each be configured to connect the front port to one of the back ports in response to an input. The input may be received from the controller and may also be presented to the memory.

### BRIEF DESCRIPTION OF THE FIGURES

Embodiments of the invention will be apparent from the following detailed description and the appended claims and drawings.

FIG. 1 is a diagram illustrating an embodiment of the invention.

FIG. 2 is a block diagram illustrating an example embodiment of the invention.

FIG. 3 is a block diagram illustrating an alternate example embodiment of the invention.

FIG. 4 is a block diagram illustrating a NAND interface device to boost operation speed of a solid-state drive.

FIG. 5 is a block diagram illustrating a NAND flash multiplexer that boosts the operation speed of a solid-state drive.

FIG. 6 is a block diagram illustrating an embodiment of the invention implemented in a multi-target per channel solid-state drive.

FIG. 7 is a block diagram illustrating a NAND flash bridge that boosts the operation speed of a solid-state drive.

### DETAILED DESCRIPTION OF THE EMBODIMENTS

Embodiments of the present invention include providing a NAND interface device to boost operation speed of a solid-state drive that may (i) connect a flash controller to multiple flash memory targets, (ii) re-use a chip enable signal to select a flash memory target, (iii) be implemented without adding an extra pin from a flash controller, (iv) enable a memory bus to operate at a speed closer to the maximum potential speed of the flash memory, (v) reduce an amount of load seen by a flash controller, (vi) enable a bus to the flash controller to operate at a different speed than a bus to the flash memory target, (vii) increase bandwidth based on the number of ports available, (viii) be implemented as a system-in-package, (ix) be implemented as a multi-chip assembly and/or (x) be implemented as one or more integrated circuits.

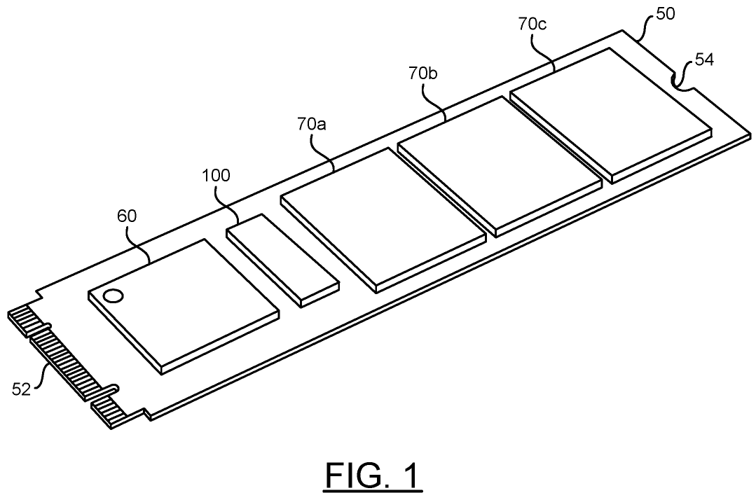

Referring to FIG. 1, a diagram illustrating an embodiment of the invention is shown. An example embodiment of a solid-state drive (SSD) 50 is shown. In the example shown, the SSD 50 may implement a Non-Volatile Memory Express (NVMe) type storage media. While a NVMe SSD 50 is shown, the SSD 50 may be implemented as other form-factors (e.g., SATA2, SATA3, PCIe, etc.). The form-factor of the SSD 50 may be varied according to the design criteria of a particular implementation.

The SSD 50 may comprise pin connectors 52 and a notch 54. The pin connectors 52 may be configured to connect the SSD 50 to a host device (e.g., a desktop computer, a laptop computer, a tablet computing device, a smartphone, etc.). The notch 54 may be a cutout on the circuit board of the SSD 50. The notch 54 may provide a space for a screw to secure the SSD 50 to another component. The screw may be inserted through the notch 54 and the head of the screw may rest on the SSD 50 to hold the SSD 50 in place on a motherboard (or PCIe adapter board or USB adapter board, etc.).

The pin connectors 52 may be a B & M-key type connector. In some embodiments, the pin connectors 52 may be a M-key type connector. In some embodiments, the pin connectors 52 may enable the SSD 50 to communicate with the host device using the PCIe 3.0 protocol using four lanes (e.g., transfer speeds of approximately 16 GBps). In some embodiments, the pin connectors 52 may enable the SSD 50 to communicate with the host device using the PCIe 4.0 protocol using up to four lanes (e.g., transfer speeds of approximately 32 GBps). In an example, the SSD 50 may be a 2280 sized drive (e.g., 22 mm×80 mm). In another example, the SSD 50 may be a 2260 sized drive (e.g., 22 mm×60 mm). Other sizes for the SSD 50 may be implemented (e.g., 2242, 22110, etc.). The size of the SSD 50, the shape of the pin connectors 52 and/or the transfer protocol implemented by the pin connectors 52 may be varied according to the design criteria of a particular implementation.

The SSD 50 may comprise a block (or circuit) 60, blocks (or circuits) 70a-70c and/or a block (or circuit) 100. The circuit 60 may implement a flash controller. The circuits 70a-70c may implement flash memory packages. The circuit 100 may implement a memory interface device. The SSD 50 may comprise other components (not shown). In an example, the SSD 50 may comprise a RAM module. The number, type and/or arrangement of the components of the SSD 50 may be varied according to the design criteria of a particular implementation.

The flash controller 60 may implement a processor configured to control and/or manage the input/output to/from the flash memory packages 70a-70c and/or the pin connectors 52 (e.g., to communicate with the hose device). In some embodiments, the transfer rate that the flash controller 60 is capable of may determine how quickly data stored in the flash memory packages 70a-70c is accessed and/or written to. The flash controller 60 may be configured to communicate data from a host computer to the flash memory packages 70a-70c. The flash controller 60 may be configured to communicate data from the flash memory packages 70a-70c to the host computer. The flash controller 60 may comprise a number of pins, each having a specified function. In one example, the flash controller 60 and/or the pin connectors 52 may be configured to operate as an NVMe interface for the SSD 50.

The flash memory packages 70a-70c may be configured to store computer readable data. The flash memory packages 70a-70c may comprise non-volatile memory. In an example, the flash memory packages 70a-70c may comprise NAND memory. The flash memory packages 70a-70c may be configured to communicate with the flash controller 60 to store (write operations) and/or provide (read operations) computer readable data. In some embodiments, the transfer rate that the flash memory packages 70a-70c are capable of may determine how quickly data is written to and/or read from the flash memory packages 70a-70c. In the example shown, three flash memory packages 70a-70c are on one side of the SSD 50. In some embodiments, the SSD 50 may comprise additional flash memory packages on a backside of the SSD 50. The SSD 50 may comprise any number of flash memory packages (e.g., 70a-70n).

The circuit 100 is shown implemented as a separate chip package from the flash controller 60 and the flash memory packages 70a-70c. In the example shown, the circuit 100 is shown implemented in between the flash controller 60 and the flash memory packages 70a-70c. The circuit 100 may be configured to boost the operation speed of the SSD 50.

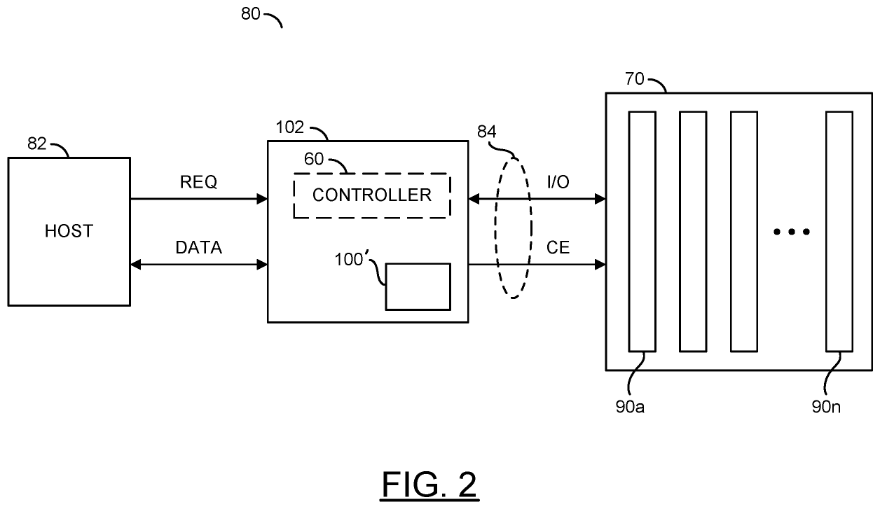

Referring to FIG. 2, a block diagram illustrating an example embodiment of the invention is shown. A system 80 is shown. The system 80 may be a block diagram of a data path for storing data to and/or retrieving data from the SSD 50. The system 80 may comprise the flash memory package 70, a block (or circuit) 82, a block (or circuit) 84 and/or a block (or circuit) 102. The flash memory package 70 may be a representative example of the flash memory packages 70a-70n shown in association with FIG. 1. The circuit 82 implement a host device (e.g., a host computer, a motherboard, a processor, a NVMe controller, etc.). The circuit 84 may be a bus. In an example, the bus 84 may be a channel bus (e.g., a NAND bus for a memory channel). The circuit 102 may implement a controller package. The system 80 may comprise other components (not shown). The number, type and/or arrangement of the components of the system 80 may be varied according to the design criteria of a particular implementation.

The controller package 102 may comprise the apparatus 100′. The apparatus 100′ may have an implementation similar to the apparatus 100 shown in association with FIG. 1. The controller package 102 may have an implementation similar to the flash controller 60 shown in association with FIG. 1. The controller package 102 may be a multi-chip assembly comprising the flash controller 60 and the apparatus 100′. While the system 80 with the multi-chip assembly 102 is described in FIG. 2, the description of the system 80 may be applicable to embodiments where the flash controller 60 and the apparatus 100 are implemented as separate components as shown in association with FIG. 1.

A signal (e.g., REQ) and a signal (e.g., DATA) are shown communicated between the host 82 and the controller package 102. A signal (e.g., I/O) and a signal (e.g., CE) are shown communicated between the controller package 102 and the flash memory package 70. Other signals may be communicated within the system 80 (not shown). The number, type and/or function of the signals implemented within the system 80 may be varied according to the design criteria of a particular implementation.

The signal REQ is shown being transmitted by the host 82 to the controller package 102. The signal REQ may be a request made by the host 82 to the flash controller 60. In an example, the signal REQ may be a data request (e.g., indicating which data to retrieve from the flash memory package 70). The signal DATA is shown as a bi-directional signal communicated by the host 82 and the controller package 102. The signal DATA may comprise computer readable data and/or high speed commands. In one example, the signal DATA may be computer readable data retrieved from the flash memory package 70 by the flash controller 60 and communicated to the host 82. In another example, the signal DATA may be computer readable data communicated by the host 82 to the flash controller 60 for storage in the flash memory package 70. In yet another example, the signal DATA may comprise high commands communicated between the host 82 and the flash controller 60.

The signal I/O is shown as a bi-directional signal communicated by the controller package 102 to the flash memory package 70. The signal I/O may comprise computer readable data and/or commands. For example, the signal I/O may present data input from the flash controller 60 to the flash memory package 70. In another example, the signal I/O may present data output read from the flash memory package 70 to the flash controller 60. In yet another example, the signal I/O may comprise commands by the flash controller 60 for the flash memory package 70. The signal CE is shown being provided by the controller package 102 to the flash memory package 70. The signal CE may be generated by the flash controller 60. The signal CE may be a chip enable signal. The chip enable signal CE may select a particular storage location of the flash memory package 70 to store the signal I/O to and/or retrieve the signal I/O from. The signal I/O and the signal CE may be communicated over the NAND bus 84

The flash memory package 70 may comprise a number of blocks (or circuits) 90a-90n. The circuits 90a-90n may be logical unit numbers (LUNs) of the flash memory package 70. In an example, each of the circuits 90a-90n may be a flash memory die integrated in the NAND flash memory package 70.

Each of the flash memory packages 70a-70n may comprise a number of the dies 90a-90n (e.g., for greater storage capacity). For a single one of the dies 90a-90n implemented in a single one of the NAND flash memory packages 70a-70n, the flash controller 60 may be capable of achieving the highest speed that both the flash memory package 70 and the flash controller 60 supports (e.g., whichever is lower). In an example, if the flash controller supports 1.2 GT/s and is paired with the die 90i that supports 0.8 GT/s, then the SSD 50 may operate at 0.8 GT/s. If multiple dies 90a-90n are implemented in the flash memory package 70 (as shown) and/or multiple packages 70a-70n are connected to the NAND channel for increased capacity, then the additional load may reduce the system speed (e.g., compared to the single die implementation).

The system 80 may represent a single NAND channel. Multiple NAND channels may be implemented in the SSD 50. In the example shown, the flash controller 60 may connect to a single flash memory package 70. In some embodiments, the flash controller 60 may connect to a group of targets (e.g., the flash memory packages 70a-70n). Each flash memory package 70a-70n may have multiple LUNs 90a-90n (e.g., dies). Each of the LUNs 90a-90n accessible (or visible or connected to) to the flash controller 60 may increase a load on the NAND bus 84. The apparatus 100 (or 100′) may be configured to reduce the load visible to the flash controller 60. Reducing the load visible to the flash controller 60 may enable the performance of the SSD 50 to increase to a throughput that is supported by the flash controller 60 and/or the flash memory packages 70-70n.

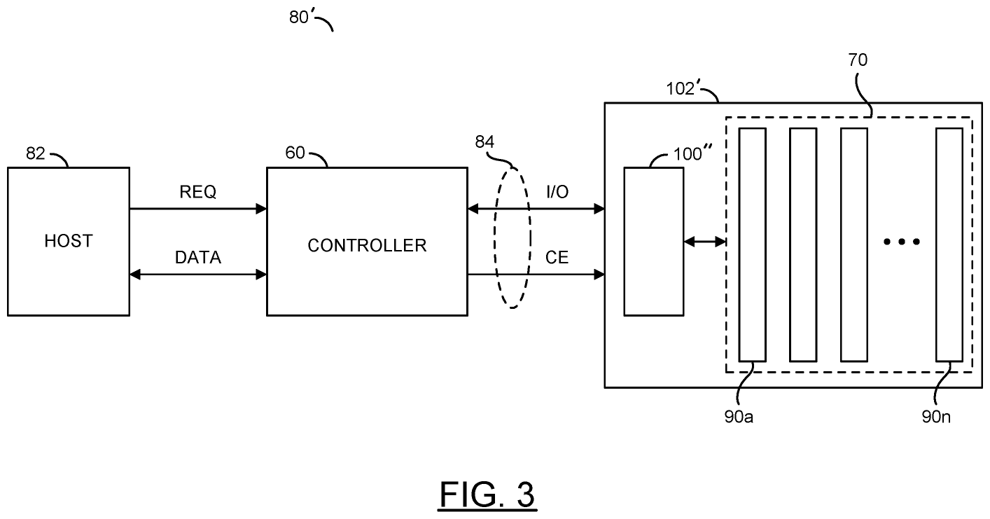

Referring to FIG. 3, a block diagram illustrating an alternate example embodiment of the invention is shown. The system 80′ is shown. The system 80′ may have an implementation similar to the system 80 shown in association with FIG. 2. The system 80′ may comprise the flash controller 80, the host 82, the NAND bus 84 and/or the circuit 102′.

The system 80′ may be an example illustrating a single channel of the SSD 50. In the example shown, the circuit 102′ may be a memory package. The memory package 102′ may comprise the apparatus 100″ and/or the flash memory package 70. The flash memory package 70 may comprise the LUNs 90a-90n (e.g., NAND dies). The memory package 102′ may comprise other components (not shown). The number, type and/or arrangement of the components of the memory package 102′ may be varied according to the design criteria of a particular implementation.

The signal REQ is shown being presented by the host 82 to the flash controller 60. The signal DATA is shown as a bi-directional signal being presented/received by the host 82 and the flash controller 60. The signal I/O is shown as a bi-directional signal on the NAND bus 84 being presented/received by the flash controller 60 and the memory package 102′. The signal CE is shown being presented by the flash controller 60 on the NAND bus 84 to the memory package 102′.

In some embodiments, the apparatus 100 may be implemented as a separate chip design. In the example SSD 50 shown in association with FIG. 1, the apparatus 100 is shown as the separate chip design (e.g., implemented as a separate package between the flash controller 60 and the flash memory packages 70a-70n). In the separate chip design, the flash controller 60 may communicate the signal I/O and/or the signal CE to the apparatus 100 and the apparatus 100 may communicate the signal I/O to the flash memory packages 70a-70n (the flash controller 60 may communicate the signal CE to the flash memory packages 70a-70n). In the separate chip design, the flash memory packages 70a-70n may communicate the signal I/O to the apparatus 100 and then the apparatus 100 may communicate the signal I/O to the flash controller 60 and the flash controller 60 may communicate the signal CE to the apparatus 100 and the flash memory packages 70a-70n.

In some embodiments, the apparatus 100 may be implemented as a multi-chip and/or system-in-package with the flash controller 60. In the example system 80 shown in association with FIG. 2, the apparatus 100′ is shown as part of the multi-chip package 102 (e.g., implemented in the same package with the flash controller 60 and separate from the flash memory packages 70a-70n). In the multi-chip design of the controller package 102, the flash controller 60 may communicate the signal I/O and/or the signal CE to the apparatus 100′ within the controller package 102 and the apparatus 100′ may communicate the signal I/O to the flash memory packages 70a-70n (the flash controller 60 may communicate the signal CE to the flash memory packages 70a-70n). In the multi-chip design of the controller package 102, the flash memory packages 70a-70n may communicate the signal I/O to the apparatus 100′ and the apparatus 100′ may communicate the signal I/O to the flash controller 60 within the controller package 102 and the flash controller 60 may communicate the signal CE to the apparatus 100′ within the controller package 102 and to the flash memory packages 70a-70n.

In some embodiments, the apparatus 100 may be implemented as a multi-chip and/or system-in-package with the flash memory package 70. In the example system 80′ shown in association with FIG. 3, the apparatus 100″ is shown as part of the multi-chip package 102′ (e.g., implemented in the same package with the flash memory package 70 and separate from the flash controller 60). In the multi-chip design of the memory package 102′, the flash controller 60 may communicate the signal I/O and/or the signal CE to the apparatus 100″ located in the memory package 102′ and the apparatus 100″ may communicate the signal I/O to the flash memory package 70 (the flash controller 60 may communicate the signal CE to the flash memory packages 70a-70n). In the multi-chip design of the memory package 102′, the flash memory packages 70a-70n may communicate the signal I/O to the apparatus 100″ within the memory package 102′ and the apparatus 100″ may communicate the signal I/O to the flash controller 60 and the flash controller 60 may communicate the signal CE to the apparatus 100″ and to the flash memory package 70 located in the memory package 102′.

The apparatus 100 may be implemented as a separated chip design. The apparatus 100 may be implemented as a monolithic integrated circuit package. The apparatus 100 may be integrated into the NAND memory packages 70a-70n in a multi-chip assembly and/or system-in-package style. In some embodiments, the flash controller 60, the apparatus 100 and the flash memory package 70 may be implemented as a single package. The single package may have an implementation similar to the separate chip design but with all the signals and components implemented within a single package. The implementation of the apparatus 100 in the SSD 50 may be varied according to the design criteria of a particular implementation.

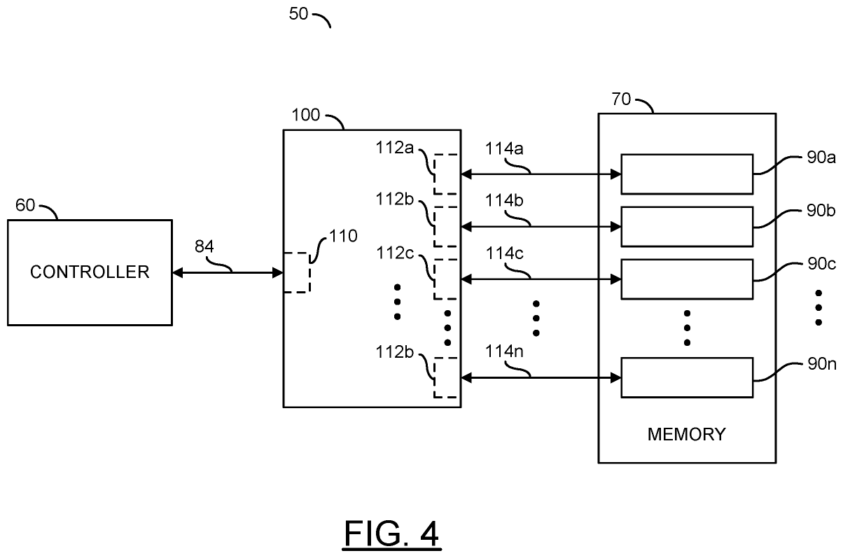

Referring to FIG. 4, a block diagram illustrating a NAND interface device to boost operation speed of a solid-state drive is shown. The components for one NAND channel of the SSD 50 are shown. The components for one NAND channel of the SSD 50 may comprise the flash controller 60, the flash memory package 70 (comprising the LUNs 90a-90n), the NAND bus 84 and/or the apparatus 100. In the example shown, the apparatus 100 may be the separate chip design similar to the example shown in FIG. 1.

The apparatus 100 may be implemented between the flash controller 60 and the flash memory package 70. The apparatus 100 may be implemented on the NAND channel bus 84. The apparatus 100 may be configured to boost the operation speed (e.g., throughput) of the SSD 50. In one example, the apparatus 100 may implement a NAND flash multiplexer configured to boost the operation speed of the SSD 50 without additional control pins from the flash controller 60. In another example, the apparatus 100 may implement a NAND flash bridge device configured to boost the operation speed of the SSD 50.

The apparatus 100 may comprise a block (or circuit) 110 and/or blocks (or circuits) 112a-112n. The circuit 110 may implement a port. The circuits 112a-112n may each implement a port. The apparatus 100 may comprise other components (not shown). The number, type and/or arrangement of the components of the apparatus 100 may be varied according to the design criteria of a particular implementation.

Connections 114a-114n are shown. The connections 114a-114n may be implemented between the apparatus 100 and the flash memory package 70. The connections 114a-114n may be discrete (e.g., separate or isolated) connections. The discrete connections 114a-114n may be a second portion of the NAND bus. For example, the bus 84 may be a first portion of the NAND bus configured to communicate data and/or commands between the flash controller 60 and the apparatus 100, and the discrete connections 114a-114n may be a second portion of the NAND bus configured to communicate data and/or commands between the apparatus 100 and the flash memory package 70. In an example, together, the bus 84, the apparatus 100 and the discrete connectors 114a-114n may implement the NAND bus.

The port 110 may implement a front port. The front port 110 may be configured to communicate with the flash controller 60. The front port 110 may be configured to receive signal(s) from the NAND bus 84. The front port 110 may be configured to present signal(s) to the NAND bus 84.

The ports 112a-112n may each implement a back port. The back ports 112a-112n may be configured to communicate with the flash memory package 70. Each of the back ports 112a-112n may be connected to a respective one of the discrete connectors 114a-114n. Each of the back ports 112a-112n may be configured to receive signal(s) from the flash memory package 70 via a respective one of the discrete connectors 114a-114n. Each of the back ports 112a-112n may be configured to present signal(s) to the flash memory package 70 via a respective one of the discrete connectors 114a-114n.

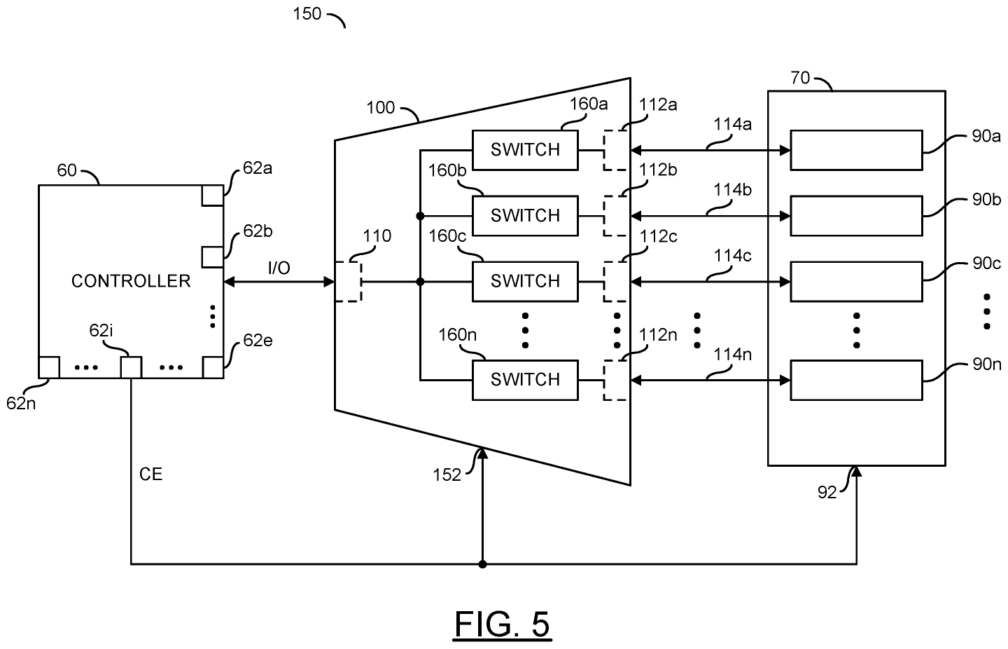

The discrete connectors 114a-114n may be connected to a respective one of the LUNs 90a-90n in the flash memory package 70. The discrete connectors 114a-114n may be configured to connect one of the back ports 112a-112n to one of the LUNs 90a-90n. The front port 110 may be configured to communicate with each of the back ports 112a-112n (to be described in more detail in association with FIGS. 5-7). By communicating with one of the back ports 112a-112n, the front port 110 may be configured to communicate individually with any one of the LUNs 90a-90n via a respective one of the discrete connectors 114a-114n. In an example, the front port 110 may connect to the back port 112a, which may enable a path to the LUN 90a via the discrete connector 114a, the front port 110 may connect to the back port 112b, which may enable a path to the LUN 90b via the discrete connector 114b, etc. Connecting the front port 110 to one of the LUNs 90a-90n may enable an isolated connection from the flash controller 60 to one of the LUNs 90a-90n.

Without the apparatus 100, the flash controller 60 may interact with the LUNs 90a-90n as a lumped load on the NAND bus 84 (e.g., the flash controller 60 sees the LUNs 90a-90n as a lumped load). Signal integrity may be reduced because of the lumped load seen by the flash controller 60. In response to the added loading of the multiple LUNs 90a-90n, the flash controller 60 may slow down the speed of the NAND bus 84 (e.g., to ensure signal integrity). Furthermore, there may be signal interference issues when addressing the multiple LUNs 90a-90n when the LUNs 90a-90n reside on a different package/port. In an example, where four of the LUNs 90a-90n are implemented, the flash controller 60 may see a lumped input capacitance due to reflections (e.g., 4×Cin, where Cin is the input capacitance of each of the LUNs 90a-90n). In order to accommodate the lumped input capacitance, the flash controller 60 may reduce the speed of the NAND bus 84 to a speed less than the throughput capability of the LUNs 90a-90n (e.g., the flash controller 60 would be unable to operate at the maximum speed that one of the LUNs 90a-90n could operate at without potentially causing errors). Furthermore, since all of the LUNs 90a-90n share the same NAND bus 84, without the apparatus 100, only one of the LUNs 90a-90n may move data to/from the flash controller 60.

The apparatus 100 may be configured to reduce the load seen by the flash controller 60 from the LUNs 90a-90n. In an example, the load may be an input capacitance. The apparatus 100 may be configured to enable the flash controller 60 to operate at throughput speeds that may be closer to the rated throughput speed of the LUNs 90a-90n. In an example, since the apparatus 100 reduces the load seen by the flash controller 60, the flash controller 60 may be able to operate at a higher speed on the NAND bus 84 without signal interference affecting the integrity of the data and/or high speed commands being transferred. The apparatus 100 may reduce the reflections on the NAND bus 84 caused by addressing multiple LUNs 90a-90n. In an example, where the apparatus 100 is implemented with four of the LUNs 90a-90n, the flash controller 60 may see an input capacitance due to reflections of one of the LUNs 90a-90 (e.g., 1×Cin, where Cin is the input capacitance of each of the LUNs 90a-90n) instead of the lumped input capacitance (e.g., 4×Cin). In an example, for n number of targets, the reduction in load seen by the flash controller 60 as a result of implementing the apparatus 100 may be approximately 1/n times the input impedance.

Referring to FIG. 5, a block diagram illustrating a NAND flash multiplexer that boosts the operation speed of a solid-state drive is shown. An implementation 150 is shown. The implementation 150 may illustrate one channel of a data path of the SSD 50 similar to the example shown in association with FIG. 4. The implementation 150 may comprise the flash controller 60, the flash memory package 70 and/or the apparatus 100. In the implementation 150, the apparatus 100 may be configured as a NAND flash multiplexer. The NAND flash multiplexer 100 may be configured to boost the operation speed of the SSD 50.

The flash controller 60 is shown comprising blocks (or circuits) 62a-62n. The blocks 62a-62n may comprise pins/connectors of the flash controller 60. The pins/connectors 62a-62n may enable the flash controller 60 to send/receive data, commands, status signals (e.g., flags), voltage, etc. The pins/connectors 62a-62n may be implemented as surface mount pins, pins for a pin grid array, pins for a land grid array, pads for a ball grid array, etc. Each of the pins/connectors 62a-62n may correspond to a pre-defined function. The pre-defined function for the pins/connectors 62a-62n may correspond to the Open NAND Flash Interface (ONFI) standard (e.g., ONFI 4.1), a specification defined by the manufacturer of the flash controller 60, a specification defined by the manufacturer of the flash memory packages 70a-70n, etc. The number, layout and/or functionality of each of the pins/connectors 62a-62n may be varied according to the design criteria of a particular implementation.

The NAND flash multiplexer 100 may comprise, the front port 110, the back ports 112a-112n and/or a number of blocks (or circuits) 160a-160n. The circuits 160a-160n may implement switches. The NAND flash multiplexer 100 may comprise an input 152. The input 152 may be configured to receive the signal CE from the flash controller 60. The NAND flash multiplexer 100 may comprise other components, logic circuitry and/or inputs/outputs (not shown). The number, type and/or arrangement of the components, logic circuitry and/or inputs/outputs of the NAND flash multiplexer 100 may be varied according to the design criteria of a particular implementation.

The flash controller 60 may communicate the signal I/O to/from the NAND flash multiplexer 100. One or more of the pins/connectors 62a-62n may present the signal I/O to the front port 110. One or more of the pins/connectors 62a-62n may receive the signal I/O from the front port 110.

The flash controller 60 may present the signal CE to the NAND flash multiplexer 100 and the flash memory package 70. One of the pins/connectors 62a-62n may present the signal CE to the input 152 of the NAND flash multiplexer 100 and to an input 92 of the flash memory package 70. In the example shown, the pin/connector 62i may present the signal CE.

The switches 160a-160n may be implemented between the front port 110 and the back ports 112a-112n. Each one of the switches 160a-160n may be configured to connect the front port 110 to a respective one of the back ports 112a-112n. The switches 160a-160n may be implemented as high performance switches that connect the front port 110 and the back side ports 112a-112n to enable data and/or high speed commands to be transmitted in both directions.

The NAND flash multiplexer 100 may operate as a bus multiplexer that has the front port 110 connect to the flash controller 60 and multiple back side ports 112a-112n connect to the NAND targets 90a-90n. The front port 110 may communicate on the first portion of the NAND bus 84 to the flash controller 60. Each of the back ports 112a-112n may communicate on a respective one of the discrete portions of the NAND bus 114a-114n to the flash memory package 70.

The signal CE may be used by the flash controller 60 as a chip enable signal for the flash package 70. The signal CE may enable one of the NAND targets 90a-90n. The signal CE may also be presented to the NAND flash multiplexer 100 at the input 152. The signal CE may select, adjust and/or activate one of the switches 160a-160n. The NAND flash multiplexer 100 may further comprise logic circuitry to select, adjust and/or activate one of the switches 160a-160n in response to the signal CE. The switch selected by the signal CE may correspond to the NAND target selected by the signal CE. In an example, if the signal CE is configured to select the NAND target 90c in the flash memory package 70, then the apparatus 100 may be configured to activate the switch 160c in response to the signal CE.

The implementation 150 may utilize the existing functionality of the signal CE to enable an activation of one or more of the switches 160a-160n. The flash controller 60 of the SSD 50 may implement the pin/connector 62i to select one or more of the NAND targets 90a-90n regardless of whether the apparatus 100 is implemented or not. For example, the pin/connector 62i may present the signal CE to the input 92 of the flash memory package 70. The signal CE provided to the input 152 may be received from the pre-existing pin/connector 62i. Implementing the apparatus 100 and/or selecting one or more of the switches 160a-160n may not require adding an additional one of the pins/connectors 62a-62n.

The NAND flash multiplexer 100 may be configured to select one of the switches 160a-160n to connect one of the back ports 112a-112n to the front side port 110 in response to the signal CE. In some embodiments, at all times, only one of the switches 160a-160n may be active and only one of the back ports 112a-112n may be connected to the front port 110 at a time. In an example, in response to the signal CE, the NAND flash multiplexer 100 may adjust the switches 160a-160n to select one of the back ports 112a-112n and un-select each of the back ports 112a-112n that have not been selected. The selection of the switches 160a-160n may be determined by the target selection signal CE that may already be used by the flash controller 60 and the flash package 70 (e.g., usually named CEn).

In an example, the flash controller 60 may generate the signal CE to select the NAND target 90c. The signal CE may be presented by the pin 62i to the input 92 of the flash memory package 70 to select the NAND target 90c and to the input 152 of the NAND flash multiplexer 100 to select the switch 160c. Selecting the switch 160c may connect the front port 110 to the back port 112c. Connecting the front port 110 to the back port 112c may enable a path from the flash controller 60 to the apparatus 100 via the NAND bus 84 and then from the apparatus 100 to the NAND target 90c via the discrete connector 114c. The path from the flash controller 60 to the front port 110, then to the back port 112c, then to the NAND target 90c may be an isolated path.

The NAND flash multiplexer 100 may be configured to provide the isolated path from the flash controller 60 to one of the NAND targets 90a-90n. The isolated path may enable the flash controller 60 to communicate directly with a selected one of the NAND targets 90a-90n. The isolated path may prevent interference and/or noise caused by the other (e.g., unselected) NAND targets 90a-90n.

The NAND flash multiplexer 100 may use the signal CE to select the multiplexer channel. The signal CE may be used to select one of the switches 160a-160n as well as the NAND targets 90a-90n at the same time. Since the NAND flash multiplexer 100 may use the same signal CE as the flash memory package 70 at the same time, the flash controller 60 may be implemented without any additional control pins. The NAND flash multiplexer 100 may utilize the functionality of an existing pin 62a-62n for selecting the switches 160a-160n. The NAND flash multiplexer 100 may be implemented using the pre-existing and/or pre-defined functionality of the flash controller 60.

The NAND flash multiplexer 100 may select one of the switches 160a-160n and unselect the remaining (e.g., unselected) switches in response to the signal CE. When the NAND flash multiplexer 100 selects one of the switches 160a-160n in response to the signal CE, the unselected switches 160a-160n and/or ports 112a-112n may operate in a different state. The different state of operation by the unselected switches 160a-160n and/or ports 112a-112n may be configured to prevent communication and/or interference from the unselected NAND targets 90a-90n. In an example, the different state may comprise a bus holder, a pull up, a pull down, a hi-Z, etc. The type of different state implemented by the NAND flash multiplexer 100 may be varied according to the design criteria of a particular implementation.

Since the NAND flash multiplexer 100 selects one of the back ports 112a-112n and blocks the unselected back ports 112a-112n, each of the back ports 112a-112n may have fewer of the NAND targets 90a-90n to address (e.g., each of the back ports 112a-112n may address one of the LUNs 90a-90n instead of implementing a single bus capable of addressing all of the LUNs 90a-90n). A direct and/or isolated path to each of the target NANDs 90a-90n made possible by the NAND flash multiplexer 100 may enable the SSD 50 to operate closer to the maximum speed of the flash controller 60 and/or the NAND targets 90a-90n. For example, the flash controller 60 may not have to reduce the speed of the bus 84 to accommodate for signal interference because the isolation provided by the NAND flash multiplexer 100 may reduce the signal interference. Implementing the NAND flash multiplexer 100 may reduce the input impedance seen by the flash controller 60 to 1/n of the total input impedance of the NAND targets 90a-90n. For example, connecting the front port 110 to one of the back ports 112a-112n may reduce the load seen by the flash controller 60 from a lumped load corresponding to all of the NAND targets 90a-90n to a single load corresponding to one of the NAND targets 90a-90n.

In an example, where there are four of the NAND targets 90a-90n, without the apparatus 100, the flash controller may see a combined load of the NAND targets 90a-90n (e.g., 4×Cn, where Cn is the input impedance). For the example with four of the NAND targets 90a-90n, the NAND flash multiplexer 100 may be implemented with four of the back ports 112a-112n. If the flash controller 60 presents the signal CE to select the NAND target 90c, the NAND flash multiplexer 100 may activate the switch 160c in response to the signal CE. The NAND flash multiplexer 100 may select the different (e.g., blocking) state for the unselected switches 160a, 160b and 160d. The NAND flash multiplexer 100 may connect the front port 110 to the back port 112c to enable an isolated path from the flash controller 60 to the NAND target 90c via the connector 114c. Since the other NAND targets 90a, 90b and 90d may be blocked by the high impedance state of the unselected switches 160a, 160b and 160c, the flash controller 60 may see a reduced load. The flash controller 60 may see the input impedance Cn from the selected NAND target 90c, but may not see the impedance Cn from each of the unselected NAND targets 90a, 90b and 90d. By implementing the NAND flash multiplexer 100 for a system with four of the NAND targets 90a-90n, the flash controller 60 may see ¼ of the overall load of the NAND targets 90a-90n. The flash controller 60 may not suffer from the signal interference issues of multiple drops in the routing of the printed circuit board. With the NAND flash multiplexer, the SSD 50 may operate at the maximum speed that the LUN 90c may be capable of operating at.

In the example shown, each of the switches 160a-160n may be configured to connect one of the back ports 112a-112n to the front port 110 (e.g., a 1 to 1 connection). Connecting one of the back ports 112a-112n to the front port 110 may enable one of the NAND targets 90a-90n to connect to the flash controller 60. In some embodiments, one or more of the switches 160a-160n may be configured to connect the front port 110 to more than one of the back ports 112a-112n (e.g., a 1 to N implementation). Connecting the front port 110 to more than one of the back ports 112a-112n may enable the controller 60 to access more than one of the NAND targets 90a-90n (e.g., allow simultaneous transfer to multiple memory targets). Connecting the front port 110 to more than one of the back ports 112a-112n (e.g., but less than all of the back ports 112a-112n) may still reduce the combined load seen by the flash controller 60 compared to the NAND bus 84 connecting to all of the NAND targets 90a-90n.

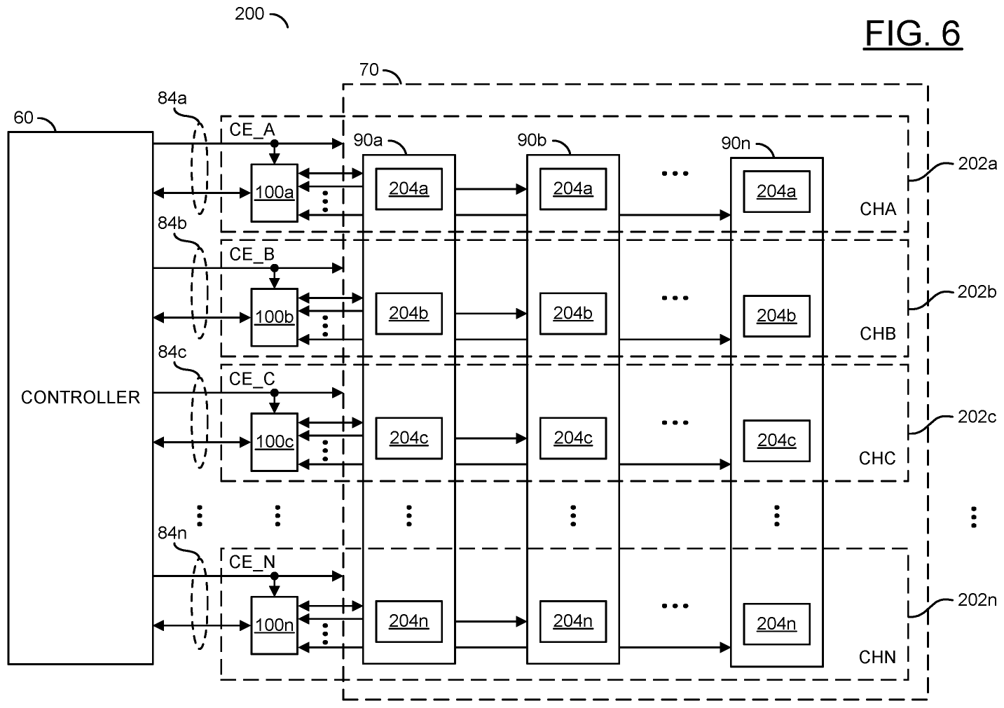

Referring to FIG. 6, a block diagram illustrating an embodiment of the invention implemented in a multi-target per channel solid-state drive is shown. A system 200 is shown. The system 200 may be an illustrative example of multiple instances of the NAND flash multiplexer 100 described in association with FIG. 5 implemented in a multi-channel embodiment of data path of the SSD 50.

The system 200 may comprise the flash controller 60 and/or the flash memory package 70. A number of data path channels (or memory channels) 202a-202n are shown. Each of the data path channels 202a-202n may have a similar implementation as the data path 150 in association with FIG. 5. The flash controller 60 may communicate with each of the data path channels 202a-202n independently. Each data path (or memory) channel 202a-202n may comprise one of the NAND buses 84a-84n and one of the NAND flash multiplexers 100a-100n. Each of the NAND buses 84a-84n may have an implementation similar to the NAND bus 84 described in association with FIG. 5. Each of the NAND flash multiplexers 100a-100n may have an implementation similar to the NAND flash multiplexer 100 described in association with FIG. 5. In the example shown, the NAND flash multiplexers 100a-100n may be separate chips. In some embodiments, the NAND flash multiplexers 100a-100n may be implemented as multiple circuits of a single chip package. Each of the data path channels 202a-202n may comprise other components (not shown). For example, each of the data path channels 202a-202n may comprise the discrete connections 114a-114n as a portion of the NAND bus from the NAND flash multiplexers 100a-100n to the flash memory package 70. The number, type and/or arrangement of the components of the data path channels 202a-202n may be varied according to the design criteria of a particular implementation.

The NAND dies 90a-90n are shown implemented across multiple of the data path channels 202a-202n. The NAND dies 90a-90n are each shown comprising blocks (or circuits) 204a-204n. The circuits 204a-204n may be data targets. Each of the data targets 204a-204n may correspond to one of the data path channels 202a-202n. In the example shown, each of the data targets 204a of the NAND dies 90a-90n are part of the data path channel 202a, each of the data targets 204b of the NAND dies 90a-90n are part of the data path channel 202b, etc. The NAND targets 204a-204n may comprise NAND chips, pages, blocks, etc.

The NAND buses 84a-84n may each comprise the signal I/O and a respective one of the chip enable signals CE_A-CE_N. The chip enable signals CE_A-CE_N may have a similar functionality as the signal CE described in association with FIG. 5. Each of the chip enable signals CE_A-CE_N may be generated independently by the flash controller 60. Each of the chip enable signals CE_A-CE_N may be configured to select one of the NAND dies 90a-90n. For example, when the chip enable CE_A selects the NAND die 90b, the flash controller 60 may read from/write to the NAND target 204a of the NAND die 90b in the data path channel 202a.

The flash controller 60 may present each of the chip enable signals CE_A-CE_N to the flash memory package 70 and to a respective one of the NAND flash multiplexers 100a-100n. Each of the NAND flash multiplexers 100a-100n may be configured to isolate a path to the selected one of the NAND dies 90a-90n in the respective one of the data path channels 202a-202n. In an example, the chip enable signal CE_A may select the NAND die 90b and may be used by the NAND flash multiplexer 100a to isolate the path between the NAND target 204a in the NAND die 90b to the flash controller 60, the chip enable signal CE_B may select the NAND die 90i and may be used by the NAND flash multiplexer 100b to isolate the path between the NAND target 204b in the NAND die 90i to the flash controller 60, the chip enable signal CE_N may select the NAND die 90a and may be used by the NAND flash multiplexer 100n to isolate the path between the NAND target 204n in the NAND die 90a to the flash controller 60, etc.

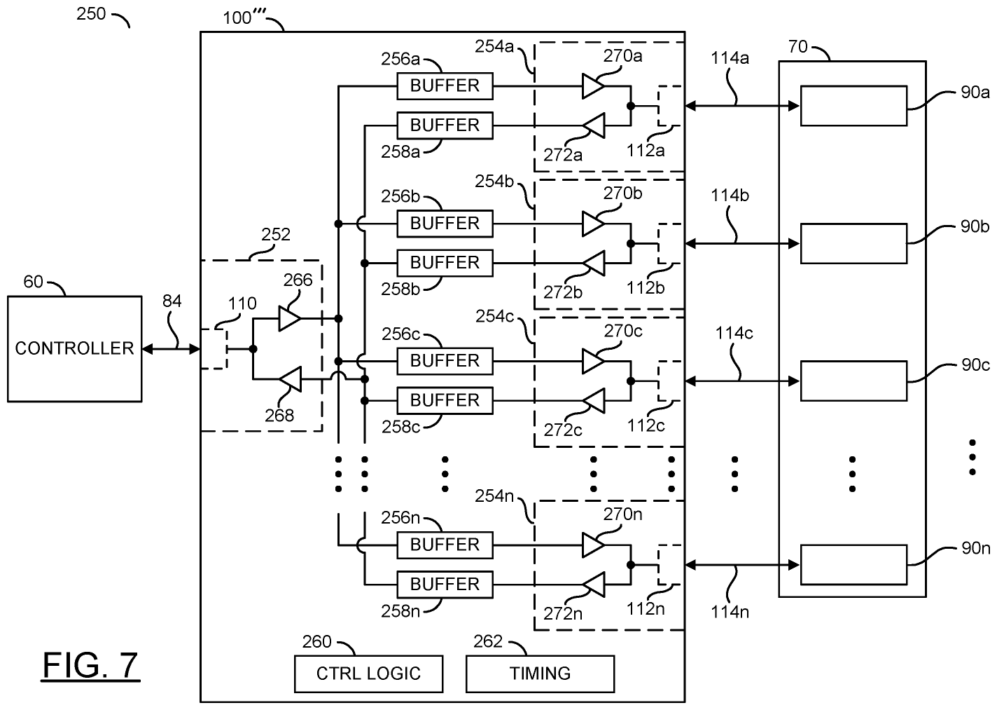

Referring to FIG. 7, a block diagram illustrating a NAND flash bridge that boosts the operation speed of a solid-state drive is shown. An implementation 250 is shown. The implementation 250 may illustrate one channel of a data path of the SSD 50 similar to the example shown in association with FIG. 4. The implementation 250 may comprise the flash controller 60, the flash memory package 70 and/or the apparatus 100′″. In the implementation 250, the apparatus 100′″ may be configured as a NAND flash bridge. The NAND flash bridge 100′″ may be configured to boost the operation speed of the SSD 50.

The flash controller 60 may communicate the signal I/O to/from the NAND flash bridge 100′″. One or more of the pins/connectors 62a-62n (not shown) of the flash controller 60 may present the signal I/O to the front port 110. One or more of the pins/connectors 62a-62n of the flash controller 60 may receive the signal I/O from the front port 110. The signal I/O may be communicated on the portion of the NAND bus 84.

The flash memory package 70 may communicate with one or more of the back ports 112a-112n. Each of the LUNs 90a-90n of the flash memory package 70 may be connected to a respective one of the back ports 112a-112n via the discrete connectors 114a-114n. The multiple back ports 112a-112n may connect to the multiple NAND targets 90a-90n.

The NAND flash bridge 100′″ may comprise, a block (or circuit) 252, a number of blocks (or circuits) 254a-254n, a number of blocks (or circuits) 256a-256n, a number of blocks (or circuits) 258a-258n, a block (or circuit) 260 and/or a block (or circuit) 262. The circuit 252 may implement a front bridge circuit. The circuits 254a-254n may each implement a back bridge circuit. The circuits 256a-256n may each implement a forward buffer. The circuits 258a-258n may each implement a reverse buffer. The block 260 may implement control logic. The circuit 262 may implement a timing circuit. The NAND flash bridge 100′″ may comprise other components and/or inputs/outputs (not shown). The number, type and/or arrangement of the components and/or inputs/outputs of the NAND flash bridge 100′″ may be varied according to the design criteria of a particular implementation.

The front bridge circuit 252 may comprise the front port 110, a block (or circuit) 266 and/or a block (or circuit) 268. The front port 110 may be configured to connect to the flash controller 60. The circuit 266 may be configured to communicate data and/or commands in a forward direction (e.g., from the flash controller 60 to the flash memory package 70). The circuit 268 may be configured to communicate data and/or commands in a reverse direction (e.g., from the flash memory package 70 to the flash controller 60). The circuits 266-268 may implement a bridge. The bridge 266-268 may be configured to enable signals to pass in one direction while blocking signals from passing in another direction. In an example, the bridge 266-268 may be implemented using IO drivers. The implementation of the bridge 266-268 may be varied according to the design criteria of a particular implementation.

Each of the back bridge circuits 254a-254n may comprise a respective one of the back ports 112a-112n, a respective one of the blocks (or circuits) 270a-270n and/or a respective one of the blocks (or circuits) 272a-272n. The back ports 112a-112n may each be configured to connect to the flash memory package 70. The back ports 112a-112n may each connect to a respective one of the LUNs 90a-90n via the discrete connectors 114a-114n. The circuits 270a-270n may each be configured to communicate data and/or commands in a forward direction (e.g., from the flash controller 60 to the flash memory package 70). The circuits 272a-272n may each be configured to communicate data and/or commands in a reverse direction (e.g., from the flash memory package 70 to the flash controller 60). The respective pairs of the circuits 270a/272a-270n/272n may each implement a bridge. Each bridge 270a/272a-270n/272n may be configured to enable signals to pass in one direction while blocking signals from passing in another direction. In an example, each of the bridges 270a/272a-270n/272n may be implemented using IO drivers. The implementation of the bridges 270a/272a-270n/272n may be varied according to the design criteria of a particular implementation.

The forward buffer circuits 256a-256n may be configured to temporarily store (e.g., buffer) data in the forward direction. The circuit 266 may connect to each of the forward buffer circuits 256a-256n. Each of the forward buffer circuits 256a-256n may connect to a respective one of the circuits 270a-270n. The forward buffer circuits 256a-256n may enable a forward data path from the flash controller 60, to the portion of the NAND data bus 84, to the front port 110, to the circuit 266, to the forward buffer circuits 256a-256n, to the circuits 270a-270n, to the back ports 112a-112n, to the discrete portions of the NAND bus 114a-114n and then to the LUNs 90a-90n.

The reverse buffer circuits 258a-258n may be configured to temporarily store (e.g., buffer) data in the reverse direction. Each of the circuits 272a-272n may connect to a respective one of the reverse buffer circuits 258a-258n. Each of the reverse buffer circuits 258a-258n may connect to the circuit 268. The reverse buffer circuits 258a-258n may enable a reverse data path from the LUNs 90a-90n, to the discrete portions of the NAND data bus 114a-114n, to the back ports 112a-112n, to the circuits 272a-272n, to the reverse buffer circuits 258a-258n, to the circuit 268, to the front port 110, to the portion of the NAND bus 84 and then to the flash controller 60.

The control logic circuit 260 may be configured to provide input to the components of the NAND flash bridge 100′″ (e.g., circuit 266, the circuit 268, the forward buffer circuits 256a-256n, the reverse buffer circuits 258a-258n, the circuits 270a-270n and/or the circuits 272a-272n). The input provided by the control logic circuit 260 may determine which of the components of the NAND flash bridge 100′″ may be enabled and which of the components of the NAND flash bridge 100′″ may be disabled.

The timing circuit 262 may be configured to provide input to the control logic 260. The timing circuit 262 may determine when the components of the NAND flash bridge 100′″ may be activated or deactivated. For example, the timing circuit 100′″ may determine that a particular one of the forward buffers 256a-256n should be activated, and provide input to the control logic 260 to enable the particular one of the forward buffers 256a-256n.

Together, the control logic 260 and/or the timing circuit 262 may be configured to control the flow of data and/or commands through the NAND flash bridge 100′″. In one example, by activating/deactivating one or more of the forward buffers 256a-256n, the control logic 260 and/or the timing circuit 262 may determine which of the back ports 112a-112n are connected to the front port 110 to enable the flash controller 60 to communicate with one of the NAND targets 90a-90n. In another example, by activating/deactivating one or more of the reverse buffers 258a-258n, the control logic 260 and/or the timing circuit 262 may determine which of the back ports 112a-112n are connected to the front port 110 to enable one of the NAND targets 90a-90n to communicate with the flash controller 60.

The front bridge circuit 252, the back bridge circuits 254a-254n, the forward buffers 256a-256n and the reverse buffers 258a-258n may be configured to enable the front port 110 and the back ports 112a-112n to forward any command and/or transaction between the flash controller 60 and the flash memory package 70 in both directions. The apparatus 100′″ may be configured to enable each of the back ports 112a-112n to independently operate at the same time (e.g., have independent operation). The transaction data may be buffered in the forward buffers 256a-256n and/or the reverse buffers 258a-258n to allow front port 110 and the back side ports 112a-112n to operate at different speeds. For example, the portion of the NAND bus 84 to the flash controller 60 may operate at a different speed (or throughput) than the portion of the NAND bus comprising the discrete connectors 114a-114n to the flash memory package 70.

Since the back ports 112a-112n may have fewer of the NAND targets 90a-90n to address (e.g., one in the example shown) compared to an implementation without the NAND flash bridge 100′″, each of the ports 112a-112n may operate at a throughput that is approximately the maximum interface speed of the flash memory package 70. The high speed commands and/or data transfer may be buffered in the data path of the NAND flash bridge 100′″ between the front port 110 and back side ports 112a-112n. By operating independently, the back side ports 112a-112n may operate simultaneously. Since all of the back side ports 112a-112n may be configured to transfer the data at the same time, the NAND flash bridge 100′″ may provide an aggregated bandwidth and/or transfer rate (or throughput) to the front port 110. In the example shown with the NAND flash bridge 100′″ having n of the back ports 112a-112n, the NAND flash bridge 100′″ may provide n (e.g., the number of ports) times of aggregated bandwidth to the front side port 110.

In an example where the NAND flash bridge 100′″ implements four of the back ports 112a-112n, the components of the NAND flash bridge 100′″ may enable the front port 110 to operate at four times the speed of one of the back ports 112a-112n. Each of the four back ports 112a-112n may address one of the four NAND targets 90a-90n. The back ports 112a-112n may operate at one speed (e.g., S_back). In an example, the speed S_back may be approximately a maximum speed that one of the LUNs 90a-90n is capable of communicating. The NAND flash bridge 100′″ may enable the front port 110 to operate at four times the speed S_back. Implementing the NAND flash bridge 100′″ may enable two types of speed boost for the SSD 50. One speed boost may be because the NAND flash bridge 100′″ may enable the speed S_back to achieve the speed limit of the NAND targets 90a-90n because of reduced overall load (e.g., input capacitance) and/or improved board routing topology. For example, the isolated discrete paths 114a-114n may result in the flash controller 60 not seeing the combined load of all of the LUNs 90a-90n. Another speed boost may be because the NAND flash bridge 100′″ may enable a speed (e.g., S_front) of the front port 110 to potentially achieve four times the speed S_back of the 4 back side ports 112a-112d (e.g., a higher transfer rate) since each of the back ports 90a-90n may transfer data at the same time.

The SSD 50 may be implemented with the apparatus 100 configured as the NAND flash multiplexer (described in association with FIG. 5) or the NAND flash bridge (e.g., described in association with FIG. 7). The SSD 50 may not implement both the NAND flash multiplexer 100 and the NAND flash bridge 100′″ (e.g., one or the other may be implemented).

The NAND flash multiplexer 100 may improve the operation of the SSD 50 by reducing the system load and/or improving the topology. The NAND flash multiplexer 100 may achieve support from both the flash controller 60 and the flash memory packages 70a-70n. In one example, the flash controller 60 and the flash memory packages 70a-70n may both support 1 GT/s data transfer speed. However, if there are multiple memories 90a-90n hooked up on the NAND bus 84 (e.g., without the NAND flash multiplexer 100) then the load and signal integrity issues may result in a lower practical speed of the SSD 50 of 0.5 GT/s. By implementing the NAND flash multiplexer 100, the flash controller 60 may see less direct load during operation and the SSD 50 may operate at speeds up to 1 GT/s.

The active NAND flash bridge 100′″ may improve the operation of the SSD 50 by reducing the system load, improving the topology and/or allowing all of the back ports 112a-112n to actively work independently. In one example, the flash controller 60 may support a 1.6 GT/s data transfer speed and may connect to multiple LUNs 90a-90n that each have a transfer speed of 0.8 GT/s. By implementing the NAND flash bridge 100′″, the aggregated bandwidth of the data transfer for the SSD 50 may achieve 1.6 GT/s (e.g., the maximum data transfer rate of the flash controller 60) by utilizing up to four times the 0.8 GT/s transfer rate of the LUNs 90a-90n operating at the same time (e.g., while four times the 0.8 GT/s transfer rate is higher than 1.6 GT/s, the SSD 50 may be limited to the maximum transfer rate of the fastest component).

The functions performed by the diagrams of FIGS. 1-7 may be implemented using one or more of a conventional general purpose processor, digital computer, microprocessor, microcontroller, RISC (reduced instruction set computer) processor, CISC (complex instruction set computer) processor, SIMD (single instruction multiple data) processor, signal processor, central processing unit (CPU), arithmetic logic unit (ALU), video digital signal processor (VDSP) and/or similar computational machines, programmed according to the teachings of the specification, as will be apparent to those skilled in the relevant art(s). Appropriate software, firmware, coding, routines, instructions, opcodes, microcode, and/or program modules may readily be prepared by skilled programmers based on the teachings of the disclosure, as will also be apparent to those skilled in the relevant art(s). The software is generally executed from a medium or several media by one or more of the processors of the machine implementation.

The invention may also be implemented by the preparation of ASICs (application specific integrated circuits), Platform ASICs, FPGAs (field programmable gate arrays), PLDs (programmable logic devices), CPLDs (complex programmable logic devices), sea-of-gates, RFICs (radio frequency integrated circuits), ASSPs (application specific standard products), one or more monolithic integrated circuits, one or more chips or die arranged as flip-chip modules and/or multi-chip modules or by interconnecting an appropriate network of conventional component circuits, as is described herein, modifications of which will be readily apparent to those skilled in the art(s).

The invention thus may also include a computer product which may be a storage medium or media and/or a transmission medium or media including instructions which may be used to program a machine to perform one or more processes or methods in accordance with the invention. Execution of instructions contained in the computer product by the machine, along with operations of surrounding circuitry, may transform input data into one or more files on the storage medium and/or one or more output signals representative of a physical object or substance, such as an audio and/or visual depiction. The storage medium may include, but is not limited to, any type of disk including floppy disk, hard drive, magnetic disk, optical disk, CD-ROM, DVD and magneto-optical disks and circuits such as ROMs (read-only memories), RAMs (random access memories), EPROMs (erasable programmable ROMs), EEPROMs (electrically erasable programmable ROMs), UVPROMs (ultra-violet erasable programmable ROMs), Flash memory, magnetic cards, optical cards, and/or any type of media suitable for storing electronic instructions.

The elements of the invention may form part or all of one or more devices, units, components, systems, machines and/or apparatuses. The devices may include, but are not limited to, servers, workstations, storage array controllers, storage systems, personal computers, laptop computers, notebook computers, palm computers, cloud servers, personal digital assistants, portable electronic devices, battery powered devices, set-top boxes, encoders, decoders, transcoders, compressors, decompressors, pre-processors, post-processors, transmitters, receivers, transceivers, cipher circuits, cellular telephones, digital cameras, positioning and/or navigation systems, medical equipment, heads-up displays, wireless devices, audio recording, audio storage and/or audio playback devices, video recording, video storage and/or video playback devices, game platforms, peripherals and/or multi-chip modules. Those skilled in the relevant art(s) would understand that the elements of the invention may be implemented in other types of devices to meet the criteria of a particular application.

The terms “may” and “generally” when used herein in conjunction with “is(are)” and verbs are meant to communicate the intention that the description is exemplary and believed to be broad enough to encompass both the specific examples presented in the disclosure as well as alternative examples that could be derived based on the disclosure. The terms “may” and “generally” as used herein should not be construed to necessarily imply the desirability or possibility of omitting a corresponding element.

While the invention has been particularly shown and described with reference to embodiments thereof, it will be understood by those skilled in the art that various changes in form and details may be made without departing from the scope of the invention.

1. An apparatus comprising:
a front port circuit configured to send/receive data to/from a controller via a first bus;
a plurality of back port circuits, each configured to send/receive said data to/from a respective one of a plurality of logical units of a memory package, wherein each of the back port circuits is connected to the respective one of the plurality of logical units via a respective discrete connection; and
a plurality of switch circuits, each having a first terminal configured to connect to said front port circuit and a second terminal configured to connect to a respective one of said plurality of back port circuits, wherein
(i) each of said plurality of switch circuits has a first state where the first terminal is connected to the second terminal and a second state where the first terminal is isolated from the second terminal by a high impedance,
(ii) said plurality of switch circuits are set to either said first state or said second state in response to an input signal,
(iii) said input signal is (a) received from said controller and (b) also presented to said memory package, and
(iv) connection of the controller to the respective one of the plurality of back port circuits provides an isolated path between the controller and the respective one of the plurality of logical units connected to the respective one of the plurality of back port circuits.

2. The apparatus according to claim 1, wherein connecting said front port circuit via an isolated path to said respective one of said logical units connected to said respective one of said back port circuits reduces a load seen by said controller from a lumped load corresponding to all of said plurality of logical units to a single load corresponding to the respective one of said logical units.

3. The apparatus according to claim 2, wherein said load seen by said controller comprises an input capacitance.

4. The apparatus according to claim 1, wherein said input signal is a chip enable signal generated by said controller to select one of said plurality of logical units in said memory package.

5. The apparatus according to claim 4, wherein (i) said chip enable signal is transmitted from a pin of said controller and (ii) said pin is used to communicate said chip enable signal to said memory package and said apparatus.

6. The apparatus according to claim 1, wherein (i) said controller is a flash controller for a solid state drive, (ii) said memory package comprises NAND flash memory and (iii) each of said plurality of logical units comprises a NAND target die.

7. The apparatus according to claim 6, wherein said solid state drive has a Non-Volatile Memory Express (NVMe) interface.

8. The apparatus according to claim 1, wherein said input signal is configured to adjust said plurality of switches to (i) select said respective one of said back port circuits connected to the respective one of the plurality of logical units corresponding to the input signal and (ii) un-select each of said plurality of back port circuits not connected to the respective one of the plurality of logical units corresponding to the input signal.

9. The apparatus according to claim 8, wherein each of said back port circuits that have not been selected operate in a predetermined state and said predetermined state is configurable to one of a bus holder state, a pull up state, a pull down state and a high impedance state to prevent communication with and interference from respective ones of the plurality of logical units.

10. The apparatus according to claim 1, wherein said apparatus is implemented on a channel bus for said memory package.

11. The apparatus according to claim 10, wherein (i) a solid state drive implements a plurality of said apparatus and (ii) each of said plurality of said apparatus is implemented on one of a plurality of memory channels implemented by said solid state drive.

12. The apparatus according to claim 10, wherein connecting one of said back port circuits to said front port circuit enables said channel bus to operate at approximately a maximum interface speed of the respective one of said plurality of logical units.

13. The apparatus according to claim 12, wherein (i) said controller is configured to slow down communication on said channel bus in response to a signal integrity of said data communicated on said channel bus, (ii) said signal integrity is reduced by a load seen by said controller and (iii) said channel bus operates at approximately said maximum interface speed in response to said controller seeing only a portion of an overall lumped load of said plurality of logical units.

14. The apparatus according to claim 1, wherein said input signal is a signal defined by an Open NAND Flash Interface (ONFI) standard.

15. An apparatus comprising:
a front bridge circuit configured to communicate signals in a first direction from a controller and a second direction to said controller using a single channel bus;
a plurality of back bridge circuits, each configured to communicate said signals in said first direction to a respective one of a plurality of logical units of a memory package and in said second direction from said respective one of said plurality of logical units of said memory package, wherein each of the back bridge circuits is connected to the respective one of the plurality of logical units via a respective discrete connection;
a first plurality of buffer circuits, each configured to connect said front bridge circuit to respective ones of said plurality of back bridge circuits in said first direction; and
a second plurality of buffer circuits, each configured to connect said respective ones of said plurality of back bridge circuits to said front bridge circuit in said second direction, wherein (i) implementing each of said plurality of back bridge circuits enables said plurality of back bridge circuits to have independent operation, (ii) said independent operation enables said back bridge circuits to operate simultaneously and (iii) said first plurality of buffer circuits and said second plurality of buffer circuits enable said front bridge circuit to operate at a first throughput and said plurality of back bridge circuits to operate at a plurality of second throughputs.

16. The apparatus according to claim 15, wherein each of said plurality of second throughputs is a maximum interface speed for respective ones of said plurality of logical units.

17. The apparatus according to claim 15, wherein said first throughput is an aggregate of said second throughputs between each of said plurality of back bridge circuits and said plurality of logical units.

18. The apparatus according to claim 15, wherein (i) said independent operation reduces an input capacitance seen by said controller compared to each of said logical units sharing a common bus between said memory package and said controller, and (ii) reducing said input capacitance enables a higher transfer rate of said signals.

19. The apparatus according to claim 15, wherein (i) said first plurality of buffer circuits and said second plurality of buffer circuits are configured to buffer said signals in a data path between said front bridge circuit and said plurality of back bridge circuits, and (ii) said signals comprise (a) high speed commands and (b) data.

20. The apparatus according to claim 15, wherein (i) said controller is a flash controller for a solid state drive, (ii) said memory package comprises NAND flash memory, (iii) each of said plurality of logical units comprises a NAND target die, and (iv) said apparatus is implemented on a NAND bus between said controller and said memory package.
